(19) United States
(12) Patent Application Publication
(10) Pub. No.: US 2022/0276143 A1
(43) Pub. Date: Sep. 1, 2022

(54) METHOD AND SYSTEM FOR AUTOMATIC EVALUATION OF CUTTING ELEMENT DURING WEAR TEST

(71) Applicant: SAUDI ARABIAN OIL COMPANY, Dhahran (SA)

(72) Inventors: Arturo Magana Mora, Dhahran (SA); Bodong Li, Dhahran (SA); Jianhui Xu, Dhahran (SA); Guodong Zhan, Dhahran (SA); Chinthaka P. Gooneratne, Dhahran (SA)

(73) Assignee: SAUDI ARABIAN OIL COMPANY, Dhahran (SA)

(21) Appl. No.: 17/186,905

(22) Filed: Feb. 26, 2021

(51) Int. Cl. G01N 3/58; G06N 20/00; G06K 9/62

(52) U.S. Cl. CPC G01N 3/58; G06N 20/00; G06K 9/6277; G06K 9/628; G06K 9/6262

(57) ABSTRACT

A system including one or more hardware processors for automatic evaluation of a cutting element in a wear testing device. The system includes an access module to access cutting element event analysis results from a sensor array. The system further includes a first model trained to classify a cutting element event of the cutting element according to a supervised machine learning algorithm, and output a predicted event type of the cutting element event. The system further includes a second model trained to classify a cutting element event of the cutting element according to an unsupervised machine learning algorithm, and output a predicted behavior of the cutting element event. The system further includes a controller to determine a toughness and a wear resistance of the cutting element. The system also includes an output module to generate and display a work order on a user interface of a client device.

### BACKGROUND

A cutting element is a tool or other implement used for separating or grinding another material. Some examples of a cutting element are a drill bit, a saw, a fly cutter, a knife, a lathe, a side cutter, a face cutter, a milling cutter, a grinding wheel, a hobbing cutter, and the plurality of cutters attached to an oil and gas drill bit. A cutting element may be formed of one or more solid materials, including ceramics (diamond including polycrystalline diamond compact (PDC), cemented carbides such as tungsten carbide, cubic boron nitride, aluminum oxide, silicon nitride, or SiAlONs), metals (for example, tool steel, high-speed steel, high-speed cobalt steel, cobalt, or titanium), or composites (for example cermet). Cutting elements may also be partially or fully coated with one or more materials to change the properties of the surface. Some coating materials may include black oxide (such as magnetite), tin nitride, titanium carbonitride, titanium aluminum nitride, diamond, zirconium nitride, aluminum-chromium silicon nitride, aluminum magnesium boride (Al₃Mg₃B₅₆).

It is important for many industrial processes, such as machining or oil and gas drilling, to measure and monitor the mechanical properties of a cutting element. One test frequently performed is a wear test. Wear testing involves cutting a hard material with a cutting element, measuring wear on the cutting element generated during cutting, and using the generated wear to quantify the wear resistance of the cutting element. Wear test may be performed for many reasons, including to scientifically study the properties of novel cutting tool materials, to spot-test a batch of cutting tools, or to measure the properties of a cutting tool prior to deployment such as downhole.

While wear testing is destructive, it may not always be performed to cutting tool failure. Furthermore, because wear testing causes damage to the cutting element, it may be useful to measure additional properties of the cutting tool during a wear test.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In general, in one aspect, embodiments relate to a system including one or more hardware processors for automatic evaluation of a cutting element in a wear testing device. The system includes an access module to access cutting element event analysis results from a sensor array. The system further includes a first model trained to classify a cutting element event of the cutting element according to a supervised machine learning algorithm, and output a predicted event type of the cutting element event. The system further includes a second model trained to classify a cutting element event of the cutting element according to an unsupervised machine learning algorithm, and output a predicted behavior of the cutting element event. The system further includes a controller to determine a toughness and a wear resistance of the cutting element. The system also includes an output module to generate and display a work order on a user interface of a client device.

In general, in one aspect, embodiments relate to assessing cutting element event analysis results from a sensor array for the cutting element in a wear testing device configured to perform a Vertical Turret Lathe test or a Horizontal Mill Wear test. The method uses a trained first multiclass classification model to classify a cutting element event of the cutting element according to a supervised machine learning algorithm, and output a predicted event type of the cutting element event during a wear test performed by the wear testing device. They method further uses a trained second multiclass classification model to classify a cutting element event of the cutting element according to an unsupervised machine learning algorithm, and output a classification indicator of a behavior of the cutting element event during the wear test performed by the wear test device. Furthermore, the method outputs a toughness and a wear resistance of the cutting element using the acoustic signal, the applied load, the temperature, a wear state, and a vibration of the cutting element, and the method also generates a work order based on the predicted corrective action and display of the work order on a user interface of a client device.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIG. 1 shows an automatic evaluation system, in accordance with one or more embodiments.

FIG. 2 shows a wear test system, in accordance with one or more embodiments.

FIG. 3A and 3B show a flowchart and an example that illustrate operations of acoustic signal processing, in accordance with one or more embodiments.

FIG. 4 shows an artificial intelligence (AI) system, in accordance with one or more embodiments.

FIG. 5 shows an example, in accordance with one or more embodiments.

FIG. 6 shows a flowchart that illustrates operations of automatic evaluation of a cutting element during the wear test, in accordance with one or more embodiments.

FIG. 7A and 7B show an example, in accordance with one or more embodiments.

FIG. 8A and 8B show systems, in accordance with one or more embodiments.

FIG. 9 shows a computer system, in accordance with one or more embodiments.

### DETAILED DESCRIPTION

Specific embodiments of the disclosure will now be described in detail with reference to the accompanying figures. Like elements in the various figures are denoted by like reference numerals for consistency.

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

In general, embodiments of the disclosure relate to a system and a method for automatic evaluation of a cutting element during wear test for measuring a wear resistance and a toughness using machine learning (ML) algorithms. In some example embodiments, the wear test may be performed in a specialized testing apparatus in the lab. In other example embodiments, the wear test may be performed in a specialized testing apparatus downhole during drilling.

In some example embodiments, the cutting element is the primary component (e.g., a drill bit, a saw, a fly cutter, a knife, a lathe, a side cutter, a face cutter, a milling cutter, a grinding wheel, a hobbing cutter, and the plurality of cutters, etc.) of oil and gas drilling tools (e.g., drill bits, reamers, mills, etc.) for drilling through various downhole formations or other components (e.g., frac plugs, liners, packers, casings, junk, etc.). For example, the cutting element may be made of one or more solid hard materials, including ceramics (diamond including polycrystalline diamond compact (PDC), cemented carbides such as tungsten carbide, polycrystalline cubic boron nitride (PcBN), aluminum oxide, silicon nitride, or SiAlONs), metals (for example, tool steel, high-speed steel, high-speed cobalt steel, cobalt, or titanium), or composites (for example cermet). The cutting elements may also be partially or fully coated with one or more materials to change the properties of the surface. Some coating materials may include, black oxide (such as magnetite), tin nitride, titanium carbonitride, titanium aluminum nitride, diamond, zirconium nitride, aluminum-chromium silicon nitride, aluminum magnesium boride (Al₃Mg₃B₅₆).

Furthermore, in some example embodiments, the properties of the wear resistance and the toughness of these cutting element are useful to design and select drill tools for various downhole conditions. Embodiments disclosed herein are directed to one or more AI algorithms (e.g., a supervised ML algorithm, a deep learning (DL) algorithm, an unsupervised ML algorithm, etc.) that may be used to automate the process to classify the wear resistance and the toughness of the cutting element during wear test based on a real-time AE signal and other sensor data (e.g., an applied load, a temperature, a wear state, and a vibration of the cutting element, etc.).

Furthermore, some embodiments herein provide a cutting element analysis result determined from a systematic correlation of the classified properties of the wear resistance and the toughness with other properties (such as the temperature, the applied load, the wear state, the vibration, etc.) measured during wear test. For example, the cutting element analysis result is assessed to optimize real-time testing parameters for each specific grade and provide guidance for drilling process optimization during the drilling process, such as adjustment of revolutions per minute (RPM), weight on bit (WOB), drilling mud rate, etc.

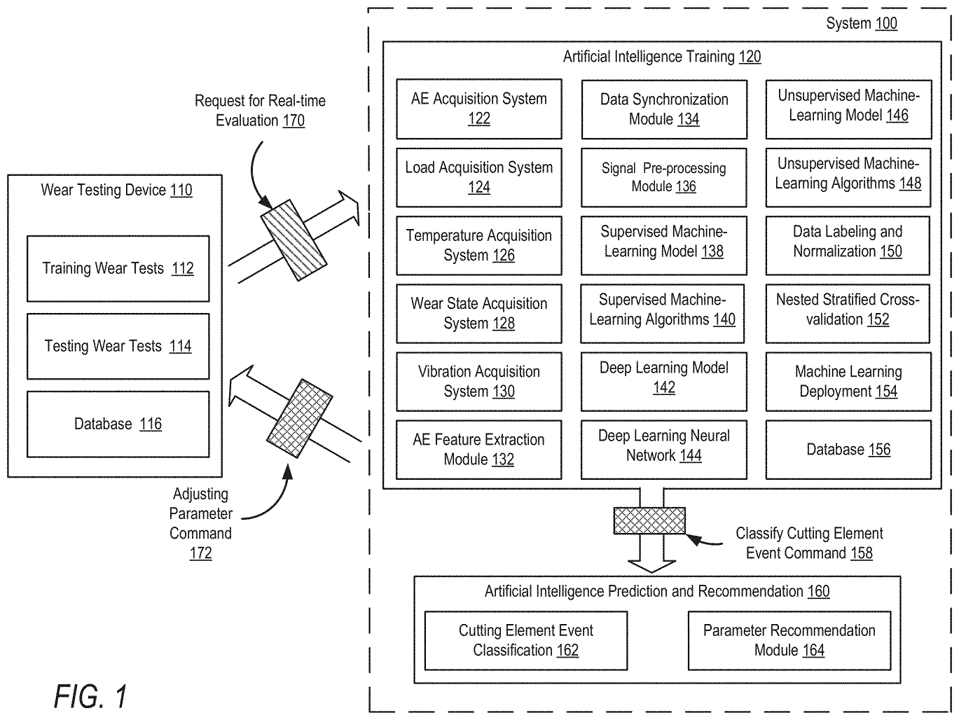

FIG. 1 is a block diagram that illustrates a diagnostic and correction system (100), according to one or more example embodiments. As shown in FIG. 1, a system (100) may be a software and hardware system which includes an AI training component (120) and an AI prediction and recommendation component (160) that are coupled to a wear testing device (110). In some example embodiments, the system (100) accesses a plurality of cutting element events stored on a database (156), and uses the cutting element events to train a plurality of ML models (e.g., a supervised ML model (138), a DL model (142), an unsupervised ML model (146)) to classify the toughness and the wear resistance of the cutting element deployed in a wear testing device. In some example embodiments, the system (100) predicts a corrective action based on the toughness and the resistance of the cutting element. In some example embodiments, the wear resistance may be determined from the event type of the cutting element events which are classified by a plurality of ML models as “aberrant cutting behaviour (anomalies)”, “cracked cutting elements”, “suboptimal rate of penetration (ROP)”, and “excessive cutting wear”, etc. In one or more embodiments, the system (100) may assess the magnitude and quantity of AE signal(s) to determine the toughness of the cutting element under a load during wear test. In some example embodiments, the software system (100) indicates the reason of a cutting element event and recommends the suggested load, ROP, RPM, WOB, drilling mud rate, etc.

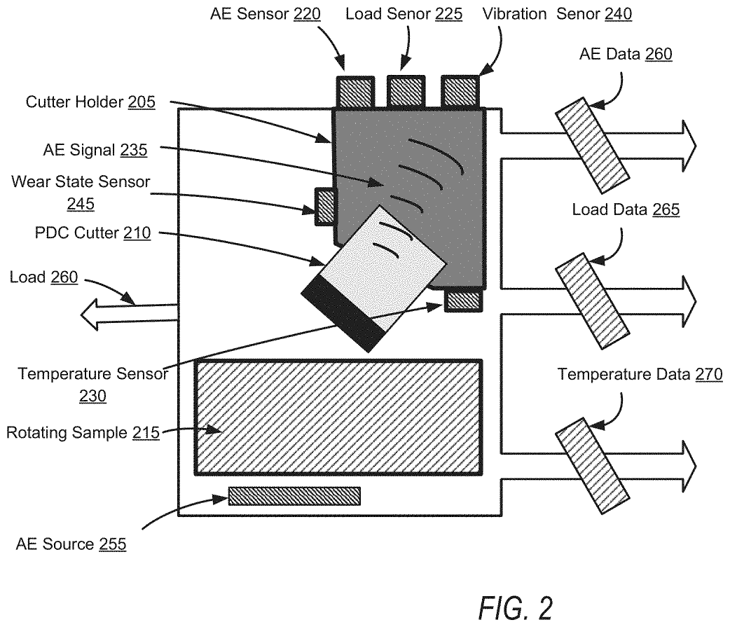

In some example embodiments, the wear testing device (110) may perform a plurality of training wear tests (112) and testing wear tests (114), and store a data obtained from a sensor array on a database (116). For example, the sensor array which is coupled to the wear testing device detects an AE signal, an applied load, a temperature, a wear state, and a vibration of the cutting element occurring during wear test performed by the wear testing device. In some example embodiments, the training wear tests (112) and the testing wear tests (114) may be performed in at least two types of wear test setups (e.g., a Vertical Turret Lathe (VTL) test and a Horizontal Mill Wear (HMW) test). Those skilled in art will appreciate that embodiments disclosed herein are not limited to the aforementioned types of wear tests, and that any suitable wear test setup may be employed to obtain a wear state and/or toughness of the cutting element during wear test. Further detail on the wear test is provided below in FIG. 2 and the accompanying description.

Continuing with FIG. 1, the diagnostic and correction system (100) includes functionality for sending an adjusting parameter command (172) in response to a request (e.g., request for real-time evaluation (170)) using AI training component (120) and AI prediction and recommendation component (160). In one or more embodiments, the AI training component (120) assesses the cutting element event data acquired by various sensor acquisition systems (e.g., an AE acquisition system (122), a load acquisition system (124), a temperature acquisition system (126), a wear state acquisition system (128), and a vibration acquisition system (130)). For example, the AE acquisition system (122) is communicably connected to an AE sensor (220) that measures AE signal(s) (235) associated with the wear state of the cutting element. The load acquisition system (124) is communicably connected to a loader sensor (225) that measures an applied load. The temperature acquisition system (126) is communicably connected to a temperature sensor (230) that measures a temperature. The wear state acquisition system (128) is communicably connected to a wear state sensor (245) that measures a wear state of the cutting element. The vibration acquisition system (130) is communicably connected to a vibration sensor (240) that measures a vibration of the cutting element.

In some example embodiments, the AI training component (120) may be a software and hardware system which includes functionality to pre-process the AE signal obtained from the sensor array (e.g., AE feature extraction module (132), data synchronization module (134), and signal pre-processing module (136), etc.) to extract a plurality of cutting element events and their features in the time domain, in the frequency domain and in the time-frequency domain. In some example embodiments, the cutting element events have at least three sources: noise of background, fracture of the testing rock sample and fracture of the cutting element. In some example embodiments, the AI training component (120) may include functionality to train a plurality of ML models (e.g., a supervised ML model (138), a DL model (142), an unsupervised ML model (146), etc.) based on extracted AE features of the cutting element events and other sensor data. For example, a supervised ML model (138) may be trained by various shallow ML algorithms (140) (e.g., random forests, decision trees, support vector machines, etc.). For example, a DL model (142) may be trained by various DL neural networks (144) (e.g., convolutional neural networks, recurrent neural networks, long short term memory networks, etc.). For example, an unsupervised ML model may be trained by various unsupervised ML algorithms (148) (e.g., k-means, k-nearest neighbours, self-organizing map, principle component analysis, etc.).

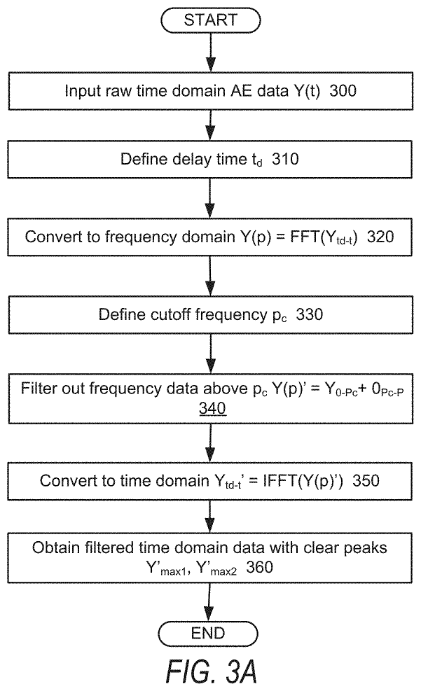

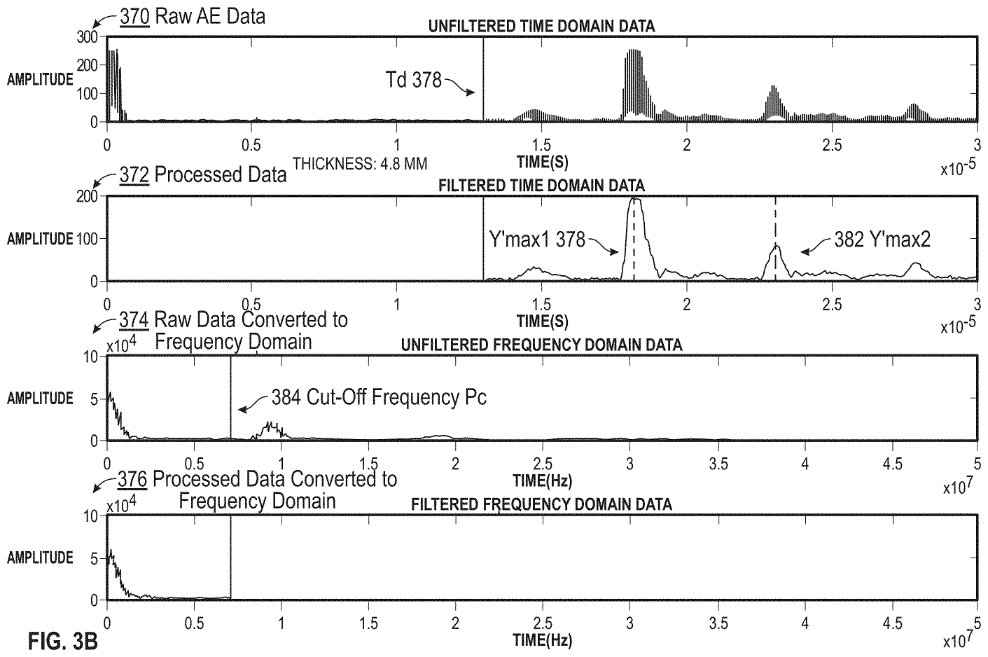

In some example embodiments, the signal pre-processing module (136) may be a software and hardware system which includes functionality to perform a Fast Fourier transform (FFT) and Inverse FFT (IFFT) to transform the AE data from the time domain to the frequency domain. In some example embodiments, other transformation methods (e.g., Hartley, Hankel, Laplace, etc.) may be applied to determine the frequencies of the two different materials and then remove the AE data associated with the testing rock sample. For more information on the signal pre-processing module (136), see FIG. 3 and the accompanying description below.

In some example embodiments, the AE feature extraction module (132) may be a software and hardware system, which includes functionality to filter the AE data with different frequencies and magnitudes to determine the cutting element events associated with the fracture of the cutting element. In some example embodiments, the cutting element events may be related to different conditions (e.g., wear resistance, cutting element damage, suboptimal cutting of rock sample, etc.) of the cutting element during wear test. In some example embodiments, the AE feature extraction module (132) determines the AE time domain features, the AE frequency domain features, and the AE time-frequency domain features by measuring various attributes of the AE signal of the cutting element events. AE time domain features (e.g., a data represented as a function of time) are associated with a non-stationary signal, where frequency components change over time due to wear and/or tear of the rotating components (e.g., the cutting element, the rotating sample, etc.). The AE frequency domain features (e.g, a data represented as a function of frequency) are associated with the condition monitoring of the cutting element. The AE time-frequency domain features (e.g., a data represented as a function of both time and frequency) are associated with the change of the condition monitoring over time of the cutting element. Consequently, the AE time domain features, the AE frequency domain features, and the AE time-frequency domain features may be used to determine the wear resistance and the toughness of the cutting element during wear test. An example of the AE features may be found in Table 1 below:

TABLE 1
An example list of relevant AE features and other sensor data

| Domain | Features |
|---|---|
| AE | Average amplitude of each time segment |
| Time-domain | Zero crossings, number of times the signal crosses zero |
| features | within an analysis window |
| | Slope sign change, number of times the slope of the |
| | waveform changes sign within an analysis window |
| | Waveform length, cumulative length of the signal within |
| | the analysis window |
| | Willison amplitude, number of times that the change in |
| | signal amplitude exceeds a threshold |
| | Variance |
| | Autoregression coefficients, obtained from a linear |
| | autoregressive time series model |
| | Maximum amplitude |
| | Root mean square |
| | Others |
| AE | Mean and median frequency |
| Frequency- | Peak frequency |
| domain | Total power |
| features | Wavelet decomposition |
| | Wavelet decomposition difference |
| | Average amplitude in the frequency domain |
| | Amplitude ratios |
| | Others |
| AE Time- | Short-time Fourier transform |
| frequency | Bilinear time-frequency distribution function |
| domain | Modified Wigner distribution function |
| features | Gabor-Wigner distribution function |
| | Wavelet transform |
| Other sensors | Temperature |
| | Load |

In some example embodiments, the data synchronization module (134) may be a software and hardware system which includes functionality to determine an encoded data set of the cutting element events from the AE features synchronized and normalized with other data (e.g., the applied load, the temperature, the wear state, and the vibration of the cutting element).

In some example embodiments, the diagnostic and correction system (100) trains a plurality of ML models in two phases. In some example embodiments, the diagnostic and correction system (100) may use the cutting element events selected specifically for the training from the training wear tests (112) (hereinafter also “training cutting element events”) to train a ML model. In some example embodiments, the diagnostic and correction system (100) may apply the ML model to classify a plurality of event types of the cutting element events selected during a testing wear test (114) (hereinafter also “testing cutting element events”). In some example embodiments, a cutting element event may be classified as one of at least four event types: 1) aberrant cutting behaviour (anomalies), 2) cracked cutting elements, 3) suboptimal ROP, and 4) excessive cutting wear. For example, a ML model may predict the dull grading based on the AE features from wear tests, and a separate ML model may identify cracks and/or failures depending on the applied load from toughness tests.

As shown in FIG. 1, during the first phase, the diagnostic and correction system (100) may apply a supervised ML algorithm (140) and/or a DL algorithm (e.g., DL neural network (144)) to train a first multiclass model (e.g., a supervised ML model (138), a DL model (142)) when a request for real-time evaluation (170) is received to assess a cutting element. In some example embodiments, the AI training component (120) applies correct labels and normalization (e.g., data labeling and normalization (150)) to the determined cutting element events. For example, the data labeling and normalization (150) includes functionality to attach a label to a cutting element event that indicates the classification of the event type of the cutting element event into an “aberrant cutting behaviour” class (e.g., the value “0”), a “cracked cutting elements” class (e.g., the value “1”), a “suboptimal ROP” class (e.g., the value “2”) or an “excessive cutting wear” class (e.g., the value “3”). For example, the data labeling and normalization (150) includes functionality to apply various normalization to AE features of the cutting element events using a mathematical model (e.g., uniform, Gaussian, etc.). This normalization of AE features of the training and testing cutting element events applies equal or optimized weights to all the AE features to be comparable across the multiple wear tests so that a particular AE feature has the same meaning across the multiple wear tests. Although only an example embodiments have been described in detail above, those skilled in the art will readily appreciate that many modifications are possible in the example embodiments without materially departing from this invention.

In some embodiments, the AI training component (120) may use a simple data split technique to separate the encoded data set (e.g., extracted AE features, the applied load, the temperature, the wear state, and the vibration, etc.) used for the training, validation, and testing of the ML models. An example of the data split technique considers 70% of the encoded data set for model training (e.g., tuning of the model parameters), 10% of the encoded data set for validation (e.g., performance validation for each different set of model parameters), and 20% of the encoded data set for testing the final trained model. However, the data split technique may result in the over-fitting problem of the ML models with limited generalization capabilities. For example, the deployed model will underperform when predicting unseen samples.

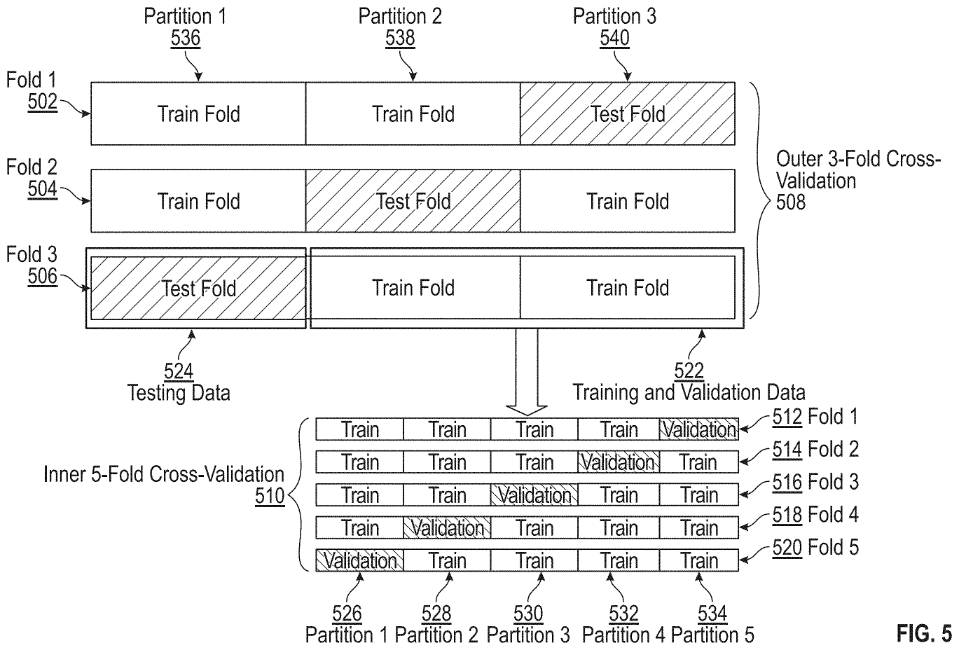

In some example embodiments, the AI training component (120) applies a nested stratified cross-validation (152) to tune and validate the optimal parameters of the first multiclass model. In some example embodiments, the nested stratified cross-validation (152) may be a software and hardware system which includes functionality to mitigate the over-fitting problem of the first multiclass model by applying an inner k-fold cross-validation and an outer k-fold cross-validation. In some example embodiments, the inner k-fold cross-validation and the outer k-fold cross-validation may have different values of the “k” parameter, In some example embodiments, the stratified cross-validation may have the same proportion of the cutting element events with a given class (e.g., an “aberrant cutting behaviour” class, a “cracked cutting elements” class, a “suboptimal ROP” class or an “excessive cutting wear” class, etc.) for each fold. In some example embodiments, the nested stratified. cross-validation (152) defines a plurality of supervised ML algorithms and their corresponding models in a grid and evaluates a performance metrics of interest (e.g., area under curve (AUC), accuracy, geometric mean, f1 score, mean absolute error, mean squared error, sensitivity, specificity, etc.) to find the optimal parameters of the first multiclass model. Although only an example embodiments have been described in detail above, those skilled in the art will readily appreciate that many modifications are possible in the example embodiments without materially departing from this invention. For more information on the nested stratified cross-validation (152), see FIG. 5 and the accompanying description below.

During the second phase, the diagnostic and correction system (100) may apply an unsupervised ML algorithm (148) to train a second multiclass model (e.g., an unsupervised ML model (146)). For example, an unsupervised ML model may be trained by an unsupervised ML algorithm (148) (e.g., k-means, k-nearest neighbours, self-organizing map, principle component analysis, etc.). In some example embodiments, the ML deployment (154) may be a software and hardware system which includes functionality to generate a command (158) and send it to the AI prediction and recommendation component (160) to apply a plurality of multiclass models to classify an event type, a wear resistance, a toughness, and parameter recommendation to mitigate the effect of failure mode (e.g., the toughness dominant failure model, wear resistance dominant failure model) of the cutting element during a testing wear test (114). In some example embodiments, the validation of the second multiclass model may be done by using labeled data (e.g., cracked, abnormal, normal, etc.) based on some performance metric (e.g., accuracy, sensitivity, specificity, etc.).

In some example embodiments, the AI prediction and recommendation component (160) may be a software and hardware system which includes functionality to calculate the toughness and classify an event type of a cutting element event (e.g., cutting element event classification (162)). In some example embodiments, the AI prediction and recommendation component (160) includes functionality to deploy the first multiclass model and/or the second multiclass model. In some example embodiments, the AI prediction and recommendation component (160) includes functionality to deploy a combination of the first multiclass model and/or the second multiclass model in a particular order. In some example embodiments, the AI prediction and recommendation component (160) includes functionality to generates a parameter recommendation (e.g., parameter recommendation system (164) to perform the corrective action to mitigate the effect of a failure mode (e.g., the toughness dominant failure model, wear resistance dominant failure model) with respect to the equipment associated with the cutting element. For example, the cutting element event classification (162) may be a software and hardware system which includes functionality to calculate the toughness and classify the event type of the cutting element event (e.g., an “aberrant cutting behaviour” class, a “cracked cutting elements” class, a “suboptimal ROP” class or an “excessive cutting wear” class, etc.). The parameter recommendation system (164) may be a software and hardware system which includes functionality to generates a parameter recommendation (e.g., load, ROP, RPM, WOB, drilling mud rate, etc.) to perform the corrective action to mitigate the effect of testing parameters on failure mode (e.g., a toughness dominant failure mode or a wear resistance dominant failure mode). The AI prediction and recommendation component (160) sends an adjusting parameter command (172) to the wear testing device (110) to change a testing parameter (e.g., load, ROP, RPM, WOB, drilling mud rate, etc.) of the cutting element during the testing wear test (114).

While FIG. 1 shows various configurations of components, other configurations may be used without departing from the scope of the disclosure. For example, various components in FIG. 1 may be combined to create a single component. As another example, the functionality performed by a single component may be performed by two or more components.

FIG. 2 shows a setup of a wear testing device in accordance with one or more embodiments. There may be two types of wear test setups: a VTL test and a HMW test. In a VTL test, the cutting element (210) is attached to the cutter holder (205) in a wear testing device. In some example embodiments, the cutting element is applied a certain depth of cut into a rotating sample (215) which may be a rock sample, such as granite. For example, the rock sample (215) rotates horizontally with the rotating axis in a vertical direction. When the PDC cutter (210) moves radially inward or outward while the rock sample (215) is rotating, the PDC cutter (210) removes a defined amount of the rock sample (215) from the flat surface on each pass. After a predetermined number of passes, the PDC cutter (210) is removed from the VTL machine for the measurement of wear characteristics (e.g., weight loss, scar area, failure mode, etc.). Various sensors (e.g., AE sensor (220), load sensor (225), temperature sensor (230), etc.) may be installed to measure a real-time AE data (260), a load data (265), a temperature data (270) and other sensor data (e.g, a wear state, a vibration) of the cutting element during the wear test.

In contrast to the VTL test setup, in a HMW test setup the rock sample (215) rotates vertically with the rotating axis in a horizontal direction. With the PDC cutter (210) moves inward while the rock sample (215) is rotating, the PDC cutter (210) removes a defined amount of the rock sample (215) from the circumference on each pass. After a predetermined number of passes, the PDC cutter (210) is removed from the HMW machine for the measurement of wear characteristics (e.g., weight loss, scar area, failure mode, etc.). Various sensors (e.g., AE sensor (220), load sensor (225), temperature sensor (230), etc.) may be installed to measure a real-time AE data (260), a load data (265), a temperature data (270) and other sensor data during the wear test.

In some example embodiments, there are two main types of toughness tests for hard cutting elements: a drop tower test and an AE test. In a drop tower test, the cutting element is carried with certain height and applied specific load to drop and hit on a steel plate. The loading energy and cycles of hit are recorded as indications of the toughness of the cutting element. In some example embodiments, the main drawback of a drop tower test is that a large quantity of the cutting elements may be used in order to draw a meaningful statistical result because the drop tower results are very scattering. At least a dozen cutting elements in one condition may be tested.

In some example embodiments, in an AE test, a sensor array detects an AE signal (235) associated with the cutting element (210) under a load (260) and an AE source (255), as shown in FIG. 2. The load (260) generates the macroscale and/or microscale fractures in the cutting element, which are detected as a real-time AE signal (235) by an AE sensor (220). In some example embodiments, the magnitude and quantity of the AE data (260), the load data (265) and the temperature data (270) are used to interpret the toughness of the cutting element, as schematically shown in FIG. 2. More specifically, in some example embodiments, the toughness of the cutting element is related to the micro-grain, or dislocation/twinning features collected by the AE signals (235) generated by the AE sensor (220) or sensor array. The AE test uses a considerably reduced amount of cutting elements in one testing condition. The high amount of field runs using these cutting elements after being tested verifies the validity of the AE test method.

FIG. 3A shows a flowchart in accordance with one or more embodiments. Specifically, FIG. 3 describes a general workflow for AE data processing based on FFT and IFFT. One or more blocks in FIG. 3A may be performed by one or more components (e.g., AE feature extraction (132), data synchronization system (134), signal preprocessing system (136)) as described in FIG. 1. While the various blocks in FIG. 3A are presented and described sequentially, one of ordinary skill in the art will appreciate that some or all of the blocks may be executed in different orders, may be combined or omitted, and some or all of the blocks may be executed in parallel. Furthermore, the blocks may be performed actively or passively.

In Block 300, the diagnostic and correction system (100) receives a raw AE data (260) received by the AE sensor (220) in accordance with one or more embodiments. For example, the raw AE data (260) obtained in time domain (raw AE data (370) in FIG. 3B) includes both noise and the cutting element events associated with various conditions (e.g., noise of background, fracture of the testing rock sample, and fracture of the cutting element). In some example embodiments, the noise lowers the resolution of the cutting element events of interest, making it difficult to identify accurate amplitude and phase of the cutting element events. In some example embodiments, various pre-processing techniques are applied to the raw AE data (370) before analysis as well as to define input AE features for the first and second multiclass models. For example, the pre-processing techniques include: 1) removing noise coherently with time-synchronous signal average, 2) isolating residual signal from a time-synchronous signal by removing the known signal components and their harmonics, 3) tracking and extracting RPM profile from the vibration signal by computing the RPM as a function of time, and 4) calculating the envelope spectrum to remove high-frequency sinusoidal components from the signal, among others.

In Block 310, a cut-off delay time t_{d} (378) in FIG. 3B is calculated to determine the start time of a cutting element event in accordance with one or more embodiments. The cut-off delay time td (378) may be expressed using the following equation:

t_{d}=Lₘₐₓ/Vₐₑ Equation 1

where Lₘₐₓ is the maximum dimension of cutter-under-test and Vₐₑ is the acoustic speed in cutter.

In Block 320, the input data (370) is transformed from the time domain to the frequency domain by implementing FFT with t_{d} in accordance with one or more embodiments. FIG. 3B shows an example of the raw data converted to frequency domain (374). In some example embodiments, other transformation methods (e.g., Hartley, Hankel, Laplace, etc.) may be applied to calculate the amplitude spectrum of the raw AE data (370) in order to separate frequencies of the two different materials and then remove the acoustic signal of the testing rock sample.

In Block 330, a cut-off frequencies p_{c} (384) as shown in FIG. 3B is obtained from a lab test in accordance with one or more embodiments. In some example embodiments, a cut-off frequencies p_{c} determines the frequency below which the raw AE data (370) may be reserved as cutting element events associated with the cutting element. In some example embodiments, a cut-off frequencies p_{c} determines the frequency above which the raw AE data (370) will be filtered out as noise or cutting element events associated with testing sample rock.

In Block 340, the noise is removed by filtering out certain intrinsic noise frequencies defined by a cut-off frequency p_{c} (384) in accordance with one or more embodiments. For example, the high frequency peak above the cut-off frequency p_{c} in the input data amplitude spectrum (374) is associated with a noise. The high frequency peak may be filtered out by applying a low pass filter to obtain a processed data in the frequency domain (376). Although only an example embodiments have been described in detail above, those skilled in the art will readily appreciate that many modifications are possible in the example embodiments without materially departing from this invention.

In Block 350, the filtered data is converted back to the time domain in accordance with one or more embodiments. In some example embodiments, an IFFT may be applied to transform the data from the frequency domain to the time domain. For example, the processed data (372) shows a better AE data (e.g., Yₘₐₓ₁′ (380), Yₘₐₓ₂′ (382)) for interpretation of the cutting element events. In some example embodiments, other transformation methods (e.g., Hartley, Hankel, Laplace, etc.) may be applied to calculate the time domain AE data in order to separate frequencies of the two different materials and then remove the acoustic signal of the testing rock sample.

In Block 360, the diagnostic and correction system (100) determines the AE data (e.g., Yₘₐₓ₁′ (380), Yₘₐₓ₂′ (382)) from the processed time domain data in accordance with one or more embodiments. In some example embodiments, the AE data may be counted to reflect the real-time toughness of the cutting element.

In some example embodiments, the characteristics of the AE features, in conjunction with the additional sensor data (the temperature, the applied load, the wear state, and the vibration, etc.), and the drilling parameters (weight applied on the cutter, RPM, etc.) may be processed by an AI algorithm (e.g., a supervised ML algorithm, a DL neural network, an unsupervised ML algorithm, etc.) for detecting various cutting elements events: 1) aberrant cutting behaviour (anomalies), 2) cracked cutting elements, 3) suboptimal ROP, and 4) excessive cutting wear, etc.

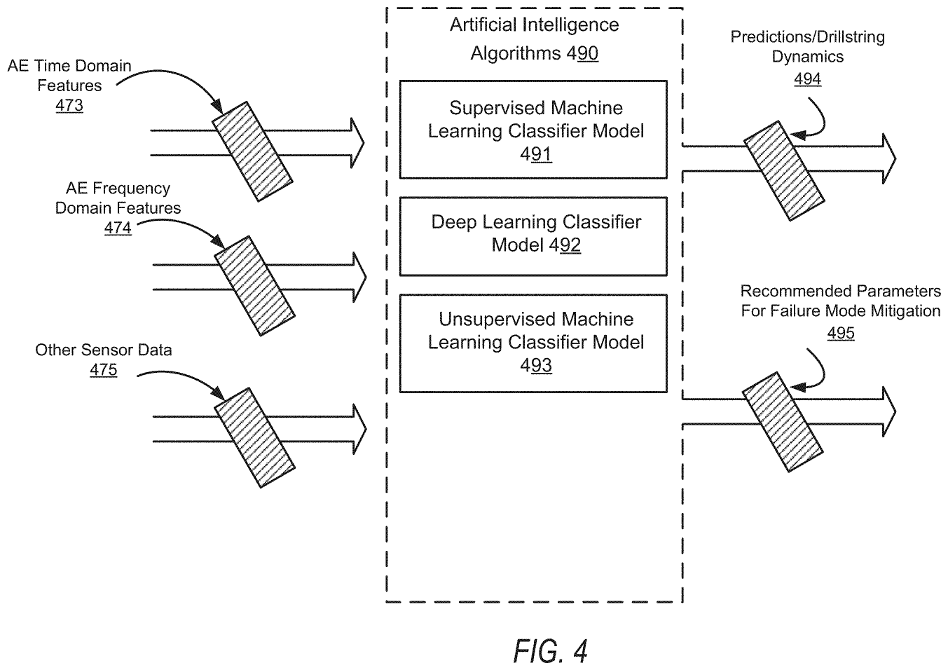

FIG. 4 shows an example of generating a model to determine an event type of the cutting element event in accordance with one or more embodiments. The following example is for explanatory purposes only and not intended to limit the scope of the disclosed technology. In FIG. 4, a first multiclass model (e.g., a supervised ML classifier model (491), a DL classifier model (492)) is trained using a supervised ML algorithm and/or a DL neural network. In particular, the first multiclass model (e.g., a supervised ML classifier model (491), a DL classifier model (492)) obtains three inputs for training, i.e., AE time domain features (473), AE frequency domain features (474), and other sensor data (475). In some example embodiments, different shallow ML or DL algorithms (e.g., random forests, decision trees, support vector machines, convolutional neural networks, recurrent neural networks, long short term memory networks, etc.) may be used to perform the classification problem.

Furthermore, in FIG. 4, a second multiclass model (e.g., an unsupervised

ML classifier model (493)) is trained using an unsupervised ML algorithm in accordance with one or more embodiments. In particular, the second multiclass model (493) obtains three inputs for training, i.e., AE time domain features (473), AE frequency domain features (474), and other sensor data (475). In some example embodiments, different clustering algorithms (e.g., k-means, k-nearest neighbours, self-organizing map, etc.) and principle component analysis may be used to perform the classification problem. Using the inputs, the AI model (e.g., a supervised ML classifier model (491), a DL classifier model (492), an unsupervised ML classifier model (493)) outputs predictions/drillstring dynamics (494) and recommended parameters for failure mode mitigation (495) to mitigate the effect of testing parameters on failure mode (e.g., a toughness dominant failure mode or a wear resistance dominant failure mode).

FIG. 5 shows an example of a nested stratified cross-validation (152) in accordance with one or more embodiments. In particular, the data split technique considers 54% of the encoded data set for model training (e.g., tuning of the model parameters), 13% of the encoded data set for validation (e.g., performance validation for each different set of model parameters), and 33% of the encoded data set for testing the final trained model.

Furthermore, for example, the inner 5-fold cross-validation (510) is performed on the encoded data set of the cutting element events (e.g., extracted AE features) used for training and validation (522) to tune the parameters of the first multiclass model. In some example embodiments, the data set used for training and validation (522) are divided in 5 mutually exclusive partitions (526, 528, 530, 532, 534), mostly by random sampling without replacement, i.e., in a dataset with S samples, each subset contains S/5 samples. In the first fold (512), 4 partitions (526, 528, 530, 532) are used for training a model which is then evaluated on the remaining partition (534). This is repeated 5 times (512, 514, 516, 518, 520), each time having different 5-th set as a test set, In each fold, some performance metric (e.g., area under curve (AUC). accuracy, geometric mean, f1 score, mean absolute error, mean squared error, sensitivity, specificity, etc.) is calculated. Afterwards, the mean value and the standard deviation of the performance metrics are calculated over 5 folds (512, 514, 516, 518, 520). A 5-fold cross-validation procedure is performed for each model to calculate the performance metric. Thus, averaged results of the 5-folds are compared for different models and finally the one that maximized the performance metrics is selected as the best model.

Furthermore, as another example, the outer 3-fold cross-validation (508) is performed on the encoded data set of the cutting element events (e.g., extracted AE features) used for testing (524) to estimate the performance and validate the parameters of the first multiclass model. In some example embodiments, the data set used for testing are divided in 3 mutually exclusive partitions (536, 538, 540), mostly by random sampling without replacement, i.e., in a dataset with S samples, each subset contains S/3 samples. In the first fold (502), 2 partitions (536, 538) are used for training a model which is then evaluated on the remaining partition (540). This is repeated 3 times (502, 504, 506), each time having different 3-th set as a test set. In each fold, some performance metric (e.g., area under curve (AUC), accuracy, geometric mean, f1 score, mean absolute error, mean squared error, sensitivity, specificity, etc.) is calculated. Afterwards, the mean value and the standard deviation of the performance metrics are calculated over 3 folds (502, 504, 506). For each model and for each set of model parameters such a 3-fold cross-validation procedure is performed, averaged results of the 3-folds are compared for different models (and/or parameter sets) and finally the one that maximized the model performance is selected as the best model. In summary, the inner k-fold cross-validation is used to tune the parameters of the model and is only performed on the training data while the outer k-fold cross-validation is used to validate the final performance of the model.

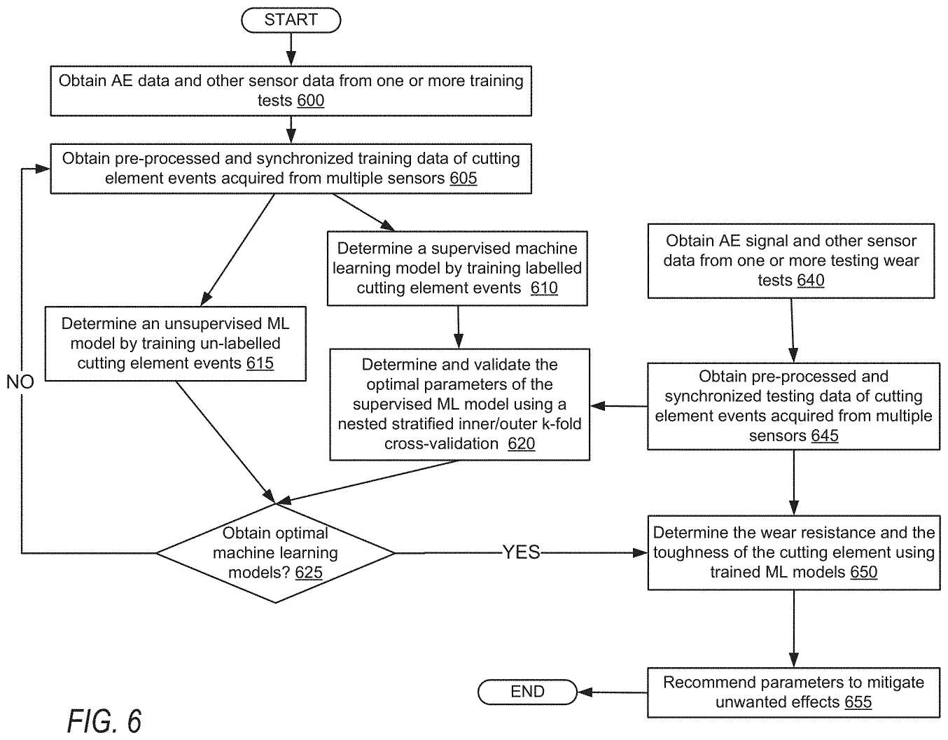

FIG. 6 shows a flowchart in accordance with one or more embodiments. Specifically, FIG. 6 describes a general method to determine an event type of the cutting element events and/or recommended parameters to mitigate the effect of testing parameters on failure mode (e.g., a toughness dominant failure mode or a wear resistance dominant failure mode) during wear test. One or more blocks in FIG. 6 may be performed by one or more components (e.g., AI training (120), AI prediction and recommendation (160)) as described in FIG. 1. While the various blocks in FIG. 6 are presented and described sequentially, one of ordinary skill in the art will appreciate that some or all of the blocks may be executed in different orders, may be combined or omitted, and some or all of the blocks may be executed in parallel. Furthermore, the blocks may be performed actively or passively.

In Block 600, the diagnostic and correction system (100) receives an AE data and other sensor data from the sensor array in a plurality of training wear tests in accordance with one or more embodiments. For example, in a training wear test, an AE data and other sensor data (e.g., an applied load, a temperature, a wear state, and a vibration) are obtained upon a request to evaluate a cutting element during wear test performed by a wear testing device.

In Block 605, the diagnostic and correction system (100) pre-processes the obtained real-time AE data and separates the cutting element events associated with various conditions (noise of background, fracture of the testing rock sample, and fracture of the cutting element) in accordance with one or more embodiments. For example, the AE data may be transformed from the time domain to the frequency domain and filter out the noise of background. The filtered AE data may be assessed to extract AE features in the time domain, in the frequency domain and in the time-frequency domain. An example of the AE features may be found in Table 1. In some example embodiments, the pre-processing workflow includes functionality for AE feature extraction, data normalization, and synchronization with other sensor data (e.g., the applied load, the temperature, the wear state, and the vibration of the cutting element).

In Block 610, the diagnostic and correction system (100) assigns a label to a set of cutting element event and trains a first multiclass model using a supervised ML algorithm and/or a DL algorithm in accordance with one or more embodiments. In some example embodiments, the cutting element events may be encoded into a plurality of data sets based on the AE features in the time domain, in the frequency domain and in the time-frequency domain. For example, the cutting element events may be encoded into four classes: 1) aberrant cutting behaviour (anomalies), 2) cracked cutting elements, 3) suboptimal ROP, 4) excessive cutting wear, 5) optimal condition, etc. In some example embodiments, different shallow ML and/or DL models may be used to perform the classification problem (e.g., random forest, decision tree, support vector machine, convolutional neural network, recurrent neural network, long short term memory network, etc.).

In Block 615, the diagnostic and correction system (100) trains a second multiclass model using an unsupervised ML algorithm in accordance with one or more embodiments. In some example embodiments, the second model is applied to classify a behavior of the cutting element event as one of a plurality of event types. For example, the second multiclass model is performed to detect outliers or aberrant behaviour of the cutting elements (chipped, cracked, etc.). In some example embodiments, different clustering algorithms (e.g., k-means, k-nearest neighbours, self-organizing map, etc.) and principle component analysis may be used to perform the classification problem.

In Block 620, the diagnostic and correction system (100) determines and validates optimal parameters of the first multiclass model in accordance with one or more embodiments. In some example embodiments, a nested stratified k-fold cross-validation technique is used to train and tune the ML/DL model parameters. For example, the inner k-fold cross-validation is used to tune the first multiclass model parameters performed on the training cutting element events. The outer k-fold cross-validation is used to validate the final performance of the first multiclass model on the testing cutting element events.

In Block 625, the diagnostic and correction system (100) obtains the optimal parameters of the ML/DL models in accordance with one or more embodiments. In some example embodiments, the diagnostic and correction system (100) deploys the ML/DL models for the characterization of the cutting element events when the trained ML/DL models are satisfactory. In some example embodiments, the diagnostic and correction system (100) re-preprocesses the cutting element events and re-trains the ML/DL models to achieve the optimal ML model.

In Block 640, the diagnostic and correction system (100) receives an AE data and other sensor data from the sensor array in a plurality of testing wear tests in accordance with one or more embodiments. For example, in a training wear test, an AE data and other sensor data (e.g., an applied load, a temperature, a wear state, and a vibration of the cutting element) are obtained upon a request to evaluate a cutting element during wear test in a wear test device.

In Block 645, the diagnostic and correction system (100) preprocesses the obtained AE data and separates the cutting element events due to various sources (noise of background, fracture of the testing rock sample, and fracture of the cutting element) in accordance with one or more embodiments. For example, the AE data may be assessed to extract important features in the time domain, in the frequency domain and in the time-frequency domain. In some example embodiments, the preprocessing workflow includes functionality for AE feature extraction, data normalization, and synchronization with other sensor data (e.g., the applied load, the temperature, the wear state, and the vibration of the cutting element).

In Block 650, the diagnostic and correction system (100) calculates the toughness and classifies event type and condition for a plurality of testing cutting element events using a plurality of ML/DL classifier models in accordance with one or more embodiments. In some example embodiments, the event type of a testing cutting element event may be classified by various classes: 1) aberrant cutting behaviour (anomalies), 2) cracked cutting elements, 3) suboptimal ROP, and 4) excessive cutting wear. In some example embodiments, the condition (e.g., wear resistance, cutting element damage, optimal cutting of rock sample, etc.) of a testing cutting element event may be predicted based on the ML/DL classifier models.

In Block 655, the diagnostic and correction system (100) recommends parameters to mitigate the effect of testing parameters on failure mode (e.g., a toughness dominant failure mode or a wear resistance dominant failure mode) for the cutting element during wear test in a wear testing device in accordance with one or more embodiments. In some example embodiments, the diagnostic and correction system (100) indicates the reason of an event and recommends the suggested load, ROP, depth of cut, RPM and cooling effect by adjusting the downhole drilling mud rate, etc.

In some example embodiments, the diagnostic and correction system (100) may automate the procedure to evaluate a cutting element during wear test based on the real-time AE data and other sensor data (e.g., the applied load, the temperature, the wear state, and the vibration of the cutting element). For example, the diagnostic and correction system (100) may obtain a real-time AE data and other sensor data (e.g., the applied load, the temperature, the wear state, and the vibration of the cutting element). In some example embodiments, the diagnostic and correction system (100) may automate the process to preprocess the real-time data and obtain a wear resistance and a toughness after a testing cycle. In some example embodiments, the diagnostic and correction system (100) may automate the process to assess the effect testing parameters on failure mode and recommend testing parameters based on the real-time correlation of AE events with other sensor data or properties per pass.

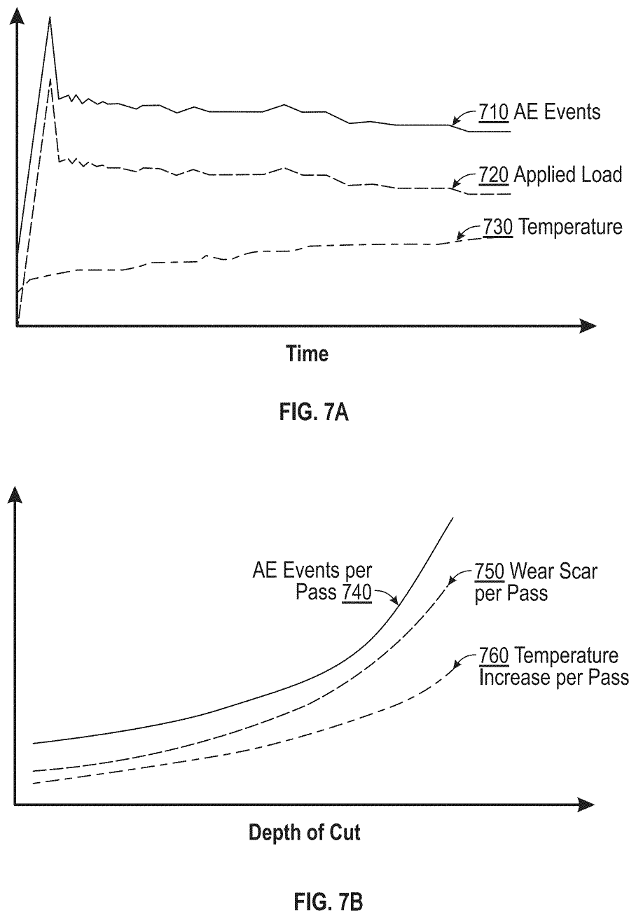

FIG. 7A shows an example of the real-time correlation of AE events (610) and other sensor data (e.g., applied load (720), temperature (730)) at different times during wear test in accordance with one or more embodiments. In some example embodiments, the diagnostic and correction system (100) assesses a schematic relationship of the AE events (710, 740) and other properties (e.g., applied load (720), temperature (730), wear scar per pass (750), temperature per pass (760), etc.) to obtain information of a cutting element during wear test. Furthermore, FIG. 7B shows an example of the real-time correlation of AE events (710) and other properties per pass (e.g., wear scar per pass (750), temperature increase per pass (760)) with different depth of cut during wear test in accordance with one or more embodiments. In some example embodiments, the diagnostic and correction system (100) assesses the effect of testing parameters on failure mode (e.g., a toughness dominant failure mode, wear resistance dominant failure mode) and generate a work load based on the predicted corrective action to mitigate the effect of testing parameters on failure mode (e.g., a toughness dominant failure mode or a wear resistance dominant failure mode) during wear test.

Furthermore, in some example embodiments, the diagnostic and correction system (100) predicts a proper grade selection of cutting elements during drill bit design and downhole application. In some example embodiments, the diagnostic and correction system (100) predicts optimal drilling parameters (e.g., depth of cut, RPM, cooling effect by adjusting the downhole drilling mud rate). In some example embodiments, the diagnostic and correction system (100) uses the recommended parameters along with the predicted cutter element events to infer the current cutter performance (e.g., optimal, suboptimal, and poor performance, etc.).

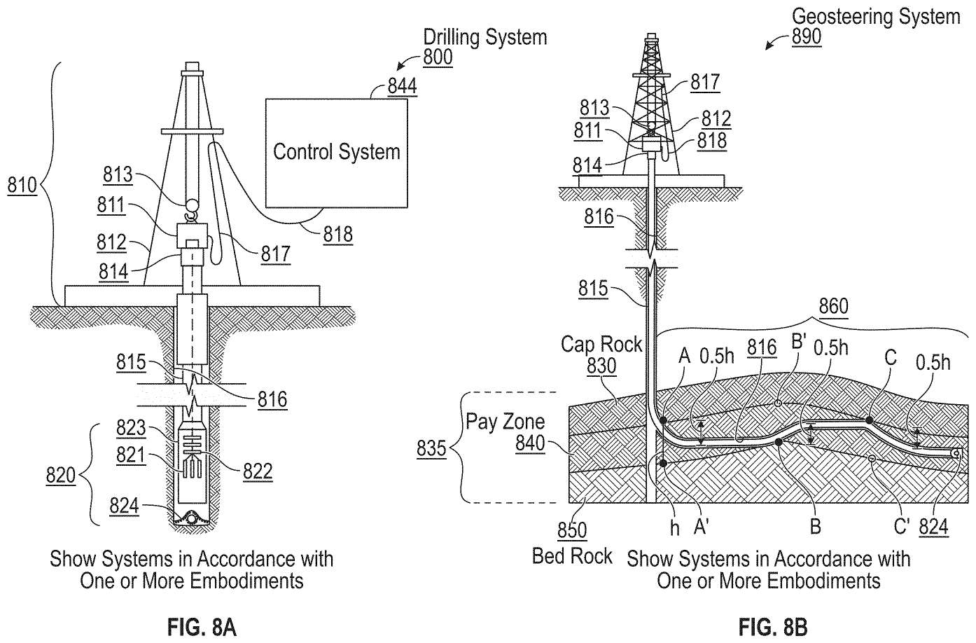

Another application of this technology is in the context of geosteering. For example, during geosteerring drilling the ML algorithms may be used to predict the best drilling parameters and cutting element in the drilling bits for the formation/rock of interest. FIGS. 8A and 8B illustrate systems in accordance with one or more embodiments. As shown in FIG. 8A, a drilling system (800) may include a top drive drill rig (810) arranged around the setup of a drill bit logging tool (820). A top drive drill rig (810) may include a top drive (811) that may be suspended in a derrick (812) by a travelling block (813). In the center of the top drive (811), a drive shaft (814) may be coupled to a top pipe of a drill string (815), for example, by threads. The top drive (811) may rotate the drive shaft (814), so that the drill string (815) and a drill bit logging tool (820) cut the rock sample at the bottom of a wellbore (816). A power cable (817) supplying electric power to the top drive (811) may be protected inside one or more service loops (818) coupled to a control system (844). As such, drilling mud may be pumped into the wellbore (816) through a mud line, the drive shaft (814), and/or the drill string (815).

Moreover, when completing a well, casing may be inserted into the wellbore (816). The sides of the wellbore (816) may require support, and thus the casing may be used for supporting the sides of the wellbore (816). As such, a space between the casing and the untreated sides of the wellbore (816) may be cemented to hold the casing in place. The cement may be forced through a lower end of the casing and into an annulus between the casing and a wall of the wellbore (816). More specifically, a cementing plug may be used for pushing the cement from the casing. For example, the cementing plug may be a rubber plug used to separate cement slurry from other fluids, reducing contamination and maintaining predictable slurry performance. A displacement fluid, such as water, or an appropriately weighted drilling mud, may be pumped into the casing above the cementing plug. This displacement fluid may be pressurized fluid that serves to urge the cementing plug downward through the casing to extrude the cement from the casing outlet and back up into the annulus.

As further shown in FIG. 8A, sensors (821) may be included in a sensor assembly (823), which is positioned adjacent to a drill bit (824) and coupled to the drill string (815). Sensors (821) may also be coupled to a processor assembly (823) that includes a processor, memory, and an analog-to-digital converter (822) for processing sensor measurements. For example, the sensors (821) may include acoustic sensors, such as accelerometers, measurement microphones, contact microphones, and hydrophones. Likewise, the sensors (821) may include other types of sensors, such as transmitters and receivers to measure resistivity, gamma ray detectors, etc. The sensors (821) may include hardware and/or software for generating different types of well logs (such as acoustic logs or density logs) that may provide well data about a wellbore, including porosity of wellbore sections, gas saturation, bed boundaries in a geologic formation, fractures in the wellbore or completion cement, and many other pieces of information about a formation. If such well data is acquired during drilling operations (i.e., logging-while-drilling), then the information may be used to make adjustments to drilling operations in real-time. Such adjustments may include ROP, drilling direction, altering mud weight, and many others drilling parameters.

In some embodiments, acoustic sensors may be installed in a drilling fluid circulation system of a drilling system (800) to record acoustic drilling signals in real-time. Drilling acoustic signals may transmit through the drilling fluid to be recorded by the acoustic sensors located in the drilling fluid circulation system. The recorded drilling acoustic signals may be processed and analyzed to determine well data, such as lithological and petrophysical properties of the rock formation. This well data may be used in various applications, such as steering a drill bit using geosteering, casing shoe positioning, etc.

The control system (844) may be coupled to the sensor assembly (823) in order to perform various program functions for up-down steering and left-right steering of the drill bit (824) through the wellbore (816). More specifically, the control system (844) may include hardware and/or software with functionality for geosteering a drill bit through a formation in a lateral well using sensor signals, such as drilling acoustic signals or resistivity measurements. For example, the formation may be a reservoir region, such as a pay zone, bed rock, or cap rock.

Turning to geosteering, geosteering may be used to position the drill bit (824) or drill string (815) relative to a boundary between different subsurface layers (e.g., overlying, underlying, and lateral layers of a pay zone) during drilling operations. In particular, measuring rock properties during drilling may provide the drilling system (800) with the ability to steer the drill bit (824) in the direction of desired hydrocarbon concentrations. As such, a geosteering system may use various sensors located inside or adjacent to the drilling string (815) to determine different rock formations within a wellbore's path. In some geosteering systems, drilling tools may use resistivity or acoustic measurements to guide the drill bit (824) during horizontal or lateral drilling.

Turning to FIG. 8B, FIG. 8B illustrates some embodiments for steering a drill bit through a lateral pay zone using a geosteering system (890). As shown in FIG. 8B, the geosteering system (890) may include the drilling system (800) from FIG. 7A. In particular, the geosteering system (890) may include functionality for monitoring various sensor signatures (e.g., an acoustic signature from acoustic sensors) that gradually or suddenly change as a well path traverses a cap rock (830), a pay zone (840), and a bed rock (850). Because of the sudden change in lithology between the cap rock (830) and the pay zone (840), for example, a sensor signature of the pay zone (840) may be different from the sensor signature of the cap rock (830). When the drill bit (824) drills out of the pay zone (840) into the cap rock (830), a detected amplitude spectrum of a particular sensor type may change suddenly between the two distinct sensor signatures. In contrast, when drilling from the pay zone (840) downward into the bed rock (850), the detected amplitude spectrum may gradually change.

During the lateral drilling of the wellbore (816), preliminary upper and lower boundaries of a formation layer's thickness may be derived from a geophysical survey and/or an offset well obtained before drilling the wellbore (816). If a vertical section (835) of the well is drilled, the actual upper and lower boundaries of a formation layer (i.e., actual pay zone boundaries (A, A′)) and the pay zone thickness (i.e., A to A′) at the vertical section (835) may be determined. Based on this well data, an operator may steer the drill bit (824) through a lateral section (860) of the wellbore (816) in real time. In particular, a logging tool may monitor a detected sensor signature proximate the drill bit (824), where the detected sensor signature may continuously be compared against prior sensor signatures, e.g., of the cap rock (830), pay zone (840), and bed rock (850), respectively. As such, if the detected sensor signature of drilled rock is the same or similar to the sensor signature of the pay zone (840), the drill bit (824) may still be drilling in the pay zone (840). In this scenario, the drill bit (824) may be operated to continue drilling along its current path and at a predetermined distance (0.5 h) from a boundary of a formation layer. If the detected sensor signature is same as or similar to the prior sensor signatures of the cap rock (830) or the bed rock (850), respectively, then the control system (844) may determine that the drill bit (824) is drilling out of the pay zone (840) and into the upper or lower boundary of the pay zone (840). At this point, the vertical position of the drill bit (824) at this lateral position within the wellbore (816) may be determined and the upper and lower boundaries of the pay zone (840) may be updated, (for example, positions B and C in FIG. 8B). In some embodiments, the vertical position at the opposite boundary may be estimated based on the predetermined thickness of the pay zone (840), such as positions B′ and C′.

While FIGS. 8A, and 8B shows various configurations of components, other configurations may be used without departing from the scope of the disclosure. For example, various components in FIGS. 8A, and 8B may be combined to create a single component. As another example, the functionality performed by a single component may be performed by two or more components.

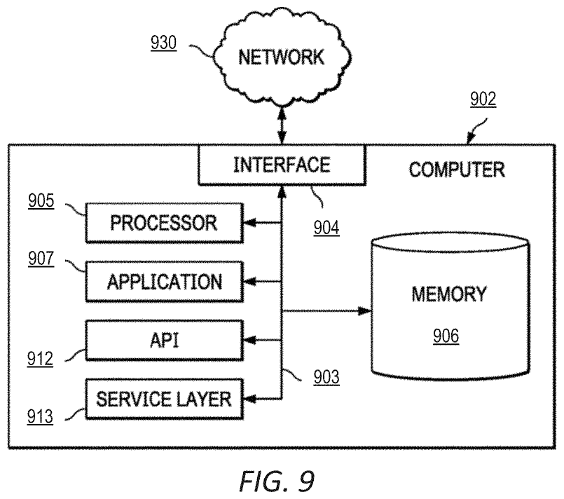

Embodiments may be implemented on a computer system. FIG. 9 is a block diagram of a computer system (902) used to provide computational functionalities associated with described algorithms, methods, functions, processes, flows, and procedures as described in the instant disclosure, according to an implementation. The illustrated computer (902) is intended to encompass any computing device such as a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer (902) may include a computer that includes an input device, such as a keypad, keyboard, touch screen, or other device that can accept user information, and an output device that conveys information associated with the operation of the computer (902), including digital data, visual, or audio information (or a combination of information), or a GUI.

The computer (902) can serve in a role as a client, network component, a server, a database or other persistency, or any other component (or a combination of roles) of a computer system for performing the subject matter described in the instant disclosure. The illustrated computer (902) is communicably coupled with a network (930). In some implementations, one or more components of the computer (902) may be configured to operate within environments, including cloud-computing-based, local, global, or other environment (or a combination of environments).

At a high level, the computer (902) is an electronic computing device operable to receive, transmit, process, store, or manage data and information associated with the described subject matter. According to some implementations, the computer (902) may also include or be communicably coupled with an application server, e-mail server, web server, caching server, streaming data server, business intelligence (BI) server, or other server (or a combination of servers).

The computer (902) can receive requests over network (930) from a client application (for example, executing on another computer (902)) and responding to the received requests by processing the said requests in an appropriate software application. In addition, requests may also be sent to the computer (902) from internal users (for example, from a command console or by other appropriate access method), external or third-parties, other automated applications, as well as any other appropriate entities, individuals, systems, or computers.

Each of the components of the computer (902) can communicate using a system bus (903). In some implementations, any or all of the components of the computer (902), both hardware or software (or a combination of hardware and software), may interface with each other or the interface (904) (or a combination of both) over the system bus (903) using an application programming interface (API) (912) or a service layer (913) (or a combination of the API (912) and service layer (913). The API (912) may include specifications for routines, data structures, and object classes. The API (912) may be either computer-language independent or dependent and refer to a complete interface, a single function, or even a set of APIs. The service layer (913) provides software services to the computer (902) or other components (whether or not illustrated) that are communicably coupled to the computer (902). The functionality of the computer (902) may be accessible for all service consumers using this service layer. Software services, such as those provided by the service layer (913), provide reusable, defined business functionalities through a defined interface. For example, the interface may be software written in JAVA, C++, or other suitable language providing data in extensible markup language (XML) format or other suitable format. While illustrated as an integrated component of the computer (902), alternative implementations may illustrate the API (912) or the service layer (913) as stand-alone components in relation to other components of the computer (902) or other components (whether or not illustrated) that are communicably coupled to the computer (902). Moreover, any or all parts of the API (912) or the service layer (913) may be implemented as child or sub-modules of another software module, enterprise application, or hardware module without departing from the scope of this disclosure.

The computer (902) includes an interface (904). Although illustrated as a single interface (804) in FIG. 9, two or more interfaces (904) may be used according to particular needs, desires, or particular implementations of the computer (902). The interface (904) is used by the computer (902) for communicating with other systems in a distributed environment that are connected to the network (930). Generally, the interface (904 includes logic encoded in software or hardware (or a combination of software and hardware) and operable to communicate with the network (930). More specifically, the interface (904) may include software supporting one or more communication protocols associated with communications such that the network (930) or interface's hardware is operable to communicate physical signals within and outside of the illustrated computer (902).

The computer (902) includes at least one computer processor (905). Although illustrated as a single computer processor (905) in FIG. 9, two or more processors may be used according to particular needs, desires, or particular implementations of the computer (902). Generally, the computer processor (905) executes instructions and manipulates data to perform the operations of the computer (902) and any algorithms, methods, functions, processes, flows, and procedures as described in the instant disclosure.

The computer (902) also includes a memory (906) that holds data for the computer (902) or other components (or a combination of both) that can be connected to the network (930). For example, memory (906) can be a database storing data consistent with this disclosure. Although illustrated as a single memory (906) in FIG. 9, two or more memories may be used according to particular needs, desires, or particular implementations of the computer (902) and the described functionality. While memory (906) is illustrated as an integral component of the computer (902), in alternative implementations, memory (906) can be external to the computer (902).

The application (907) is an algorithmic software engine providing functionality according to particular needs, desires, or particular implementations of the computer (902), particularly with respect to functionality described in this disclosure. For example, application (907) can serve as one or more components, modules, applications, etc. Further, although illustrated as a single application (907), the application (907) may be implemented as multiple applications (907) on the computer (902). In addition, although illustrated as integral to the computer (902), in alternative implementations, the application (907) can be external to the computer (902).

There may be any number of computers (902) associated with, or external to, a computer system containing computer (902), wherein each computer (902) communicates over network (930). Further, the term “client,” “user,” and other appropriate terminology may be used interchangeably as appropriate without departing from the scope of this disclosure. Moreover, this disclosure contemplates that many users may use one computer (902), or that one user may use multiple computers (902).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims. In the claims, any means-plus-function clauses are intended to cover the structures described herein as performing the recited function(s) and equivalents of those structures. Similarly, any step-plus-function clauses in the claims are intended to cover the acts described here as performing the recited function(s) and equivalents of those acts. It is the express intention of the applicant not to invoke 35 U.S.C. § 112(f) for any limitations of any of the claims herein, except for those in which the claim expressly uses the words “means for” or “step for” together with an associated function.

What is claimed is:

1. A system for automatic evaluation of a cutting element in a wear testing device, the system comprising:
one or more hardware processors;
an access module configured to access cutting element event analysis results from
a sensor array for the cutting element;
a first multiclass classification model trained to:
classify a cutting element event of the cutting element according to a supervised machine learning algorithm, and
output a predicted event type of the cutting element event during a wear test performed by the wear testing device;
a second multiclass classification model trained to:
classify a cutting element event of the cutting element according to an unsupervised machine learning algorithm, and
output a classification indicator of a behavior of the cutting element event during the wear test performed by the wear testing device;
a controller communicably connected to the sensor array and configured to determine a toughness and a wear resistance of the cutting element using an acoustic signal, an applied load, a temperature, a wear state, and a vibration of the cutting element;
an output module configured to:
generate a work order based on the predicted corrective action, and display the work order on a user interface of a client device.

2. The system of claim 1:
wherein, the access module is further configured to access cutting element event analysis results from a plurality of wear tests associated with the device, and
wherein the one or more hardware processors are configured to:
train a first multiclass classification model to:
classify a cutting element event of the cutting element according to a supervised machine learning algorithm, and
output a predicted event type of the cutting element during the wear test performed by the wear testing device;
train a second multiclass classification model to:
classify a cutting element event of the cutting element according to an unsupervised machine learning algorithm, and
output a classification indicator of a behavior of the cutting element event during the wear test performed by the wear testing device.

3. The system of claim 1, wherein the wear testing device comprises:
a sample rotation element configured to hold and to rotate a sample; and
a cutting element holder configured to hold a cutting element and to engage the cutting element with the sample as the sample rotates;

4. The system of claim 1, wherein the sensor array comprises:
an acoustic emissions sensor configured to measure an acoustic signal generated during engagement between the cutting element and the sample,
a load sensor configured to measure an applied load by the cutting element on the sample during the engagement,
a temperature sensor configured to measure a temperature of the cutting element during the engagement,
a wear sensor configured to measure a wear state of the cutting element during the engagement, and
a vibration sensor configured to measure a vibration of the cutting element during the engagement.

5. The system of claim 1, wherein the acoustic signal includes acoustic emissions generated by macroscale and microscale changes of the cutting element.

6. The system of claim 1, wherein the wear testing device is configured to perform a Vertical Turret Lathe test or a Horizontal Mill Wear test.

7. The system of claim 1, wherein the one or more hardware processors are further configured to transform the acoustic signal, the applied load, the temperature, the wear state, and the vibration for the cutting element into encoded acoustic emission data sets of time-domain feature, frequency-domain feature, time-frequency-domain features, and other sensor data.

8. The system of claim 1, wherein the one or more hardware processors are further configured to:
determine a proper grade selection of cutting elements and optimized drilling parameters, such as depth of cut, revolutions per minute, cooling effect, among others during drill bit design and downhole application; and
generate the work order based on the predicted corrective action to mitigate undesired or abnormal cutting element events.

9. The system of claim 1, wherein the toughness and the wear resistance of the cutting element are determined in real-time during the wear test.

10. The system of claim 1, wherein a transform and its inverse transform are applied to the acoustic signal to separate the acoustic signals of different sources.

11. The system of claim 10, wherein the transform may be selected from the group consisting of a Fast Fourier transform, a Wavelet transform, a Hartley transform, a Hankel transform, a Laplacian Transform, among others.

12. The system of claim 1, wherein the one or more hardware processors are further configured to analyze the event type and condition of the cutting element event using a supervised machine learning algorithm.

13. The system of claim 12,
wherein the supervised machine learning algorithm may be selected from a group consisting of a random forest algorithm, a decision tree algorithm, a support vector machine algorithm, a convolutional neural network, a recurrent neural network, among others, and
wherein a nested stratified cross-validation technique is used for the training and validation of the first multiclass model, wherein the inner k-fold cross-validation is used to tune the parameters of the first multiclass model and the outer k-fold cross-validation is used to validate the final performance of the first multiclass model.

14. The system of claim 1, wherein the one or more hardware processors are further configured to analyze a behavior of the cutting element from the plurality of training cutting element events using an unsupervised machine learning algorithm.

15. The system of claim 14, wherein the unsupervised machine learning algorithm may be selected from a group consisting of a clustering algorithm (k-means, k-nearest neighbours, self organizing map, etc.), a principal component analysis, among others.

16. A method for automatic property evaluation of a cutting element in a wear testing device, the method comprising:
assessing, by a computer processor, cutting element event analysis results from a sensor array for the cutting element in a wear testing device configured to perform a Vertical Turret Lathe test or a Horizontal Mill Wear test;
classifying, by the computer processor using a trained first multiclass classification model, a cutting element event of the cutting element according to a supervised machine learning algorithm;
outputting, by the computer processor using the trained first multiclass classification model, a predicted event type of the cutting element event during a wear test performed by the wear testing device;
classifying, by the computer processor using a trained second multiclass classification model, a cutting element event of the cutting element according to an unsupervised machine learning algorithm;
outputting, by the computer processor using the trained second multiclass classification model, a classification indicator of a behavior of the cutting element event during the wear test performed by the wear test device;
outputting, by the computer processor, a toughness and a wear resistance of the cutting element using the acoustic signal, the applied load, the temperature, a wear state, and a vibration of the cutting element;
generating, by an output module, a work order based on the predicted corrective action; and
causing, by the output module, display of the work order on a user interface of a client device.

17. The method of claim 16, wherein a transform and its inverse transform are applied to the acoustic signal to separate the acoustic signals of different sources.

18. The method of claim 17, wherein the transform may be selected from the group consisting of a Fast Fourier transform, a Wavelet transform, a Hartley transform, a Hankel transform, a Laplacian Transform, among others.

19. The method of claim 16,
wherein the supervised machine learning algorithm may be selected from a group consisting of a random forest algorithm, a decision tree algorithm, a support vector machine algorithm, a convolutional neural network, a recurrent neural network, among others, and
wherein a nested stratified cross-validation technique is used for the training and validation of the first multiclass model, wherein the inner k-fold cross-validation is used to tune the parameters of the first multiclass model and the outer k-fold cross-validation is used to validate the final performance of the first multiclass model.

20. The method of claim 16, wherein, the unsupervised machine learning algorithm may be selected from a group consisting of a clustering algorithm (k-means, k-nearest neighbours, self organizing map, etc.), a principal component analysis, among others.
